(19) United States
(12) Patent Application Publication
(10) Pub. No.: US 2020/0321236 A1
(43) Pub. Date: Oct. 8, 2020

(54) EDGE RING REMOVAL METHODS

(71) Applicant: SEMICONDUCTOR COMPONENTS INDUSTRIES, LLC, Phoenix, AZ (US)

(72) Inventor: Michael J. SEDDON, Gilbert, AZ (US)

(73) Assignee: SEMICONDUCTOR COMPONENTS INDUSTRIES, LLC, Phoenix, AZ (US)

(21) Appl. No.: 16/739,298

(22) Filed: Jan. 10, 2020

Related U.S. Application Data
(60) Provisional application No. 62/827,968, filed on Apr. 2, 2019.

(51) Int. Cl. H01L 21/687; H01L 21/78; H01L 21/306; H01L 21/3065

(52) U.S. Cl. CPC H01L 21/68735; H01L 21/3065; H01L 21/30604; H01L 21/78

(57) ABSTRACT

Implementations of methods of removing an edge support ring may include: providing a semiconductor wafer. The semiconductor wafer may include a first side and a second side. The first side of the semiconductor wafer may include a backmetal. The semiconductor wafer may also include an edge ring around a perimeter of the semiconductor wafer. The method may include mounting a first side of the semiconductor wafer to a film frame. The method may include removing a portion of the backmetal around the edge support ring and singulating the edge support ring from the semiconductor wafer.

### CROSS REFERENCE TO RELATED APPLICATIONS

This application claims the benefit of the filing date of U.S. Provisional Patent Application 62/827,968, entitled “EDGE RING REMOVAL METHODS” to Seddon, which was filed on Apr. 2, 2019, the disclosure of which is hereby incorporated entirely herein by reference.

### BACKGROUND

### 1. Technical Field

Aspects of this document relate generally to method of removing edge rings. More specific implementations involve removing rings from the edge of a semiconductor wafer.

### 2. Background

Semiconductor devices include integrated circuits found in common electrical and electronic devices, such as phones, desktops, tablets, other computing devices, and other electronic devices. Semiconductor devices are typically formed on a semiconductor substrate.

### SUMMARY

Implementations of methods of removing an edge support ring may include: providing a semiconductor wafer. The semiconductor wafer may include a first side and a second side. The first side of the semiconductor wafer may include a backmetal. The semiconductor wafer may also include an edge ring around a perimeter of the semiconductor wafer. The method may include mounting a first side of the semiconductor wafer to a film frame. The method may include removing a portion of the backmetal around the edge support ring and singulating the edge support ring from the semiconductor wafer.

Implementations of methods of removing an edge support ring may include one, all, or any of the following:

The method may include exposing the edge support ring to ultraviolet light.

The method may include lifting the edge support ring away from the semiconductor wafer.

The edge support ring may include a slope/slant.

The wafer may include a thickness less than 50 microns.

The method may include singulating the wafer into a plurality of die.

Removing the portion of backmetal may include sawing and laser.

Singulating the edge support ring from the semiconductor wafer may include plasma etching and wet etching.

Implementations of methods of removing an edge support ring may include: providing a semiconductor wafer having a first side and a second side. The first side of the semiconductor wafer may include a backmetal. The semiconductor wafer may include an edge ring around a perimeter of the semiconductor wafer. The method may include mounting a first side of the semiconductor wafer to a film frame. The method may include removing a portion of the backmetal around the edge support ring using sawing. The method may also include plasma etching at the removed portion of the backmetal to singulate the edge support ring from the semiconductor wafer. The semiconductor wafer may have a thickness of less than 50 microns.

Implementations of methods of removing an edge support ring may include one, all, or any of the following:

The method may further include exposing a tape coupled with the edge support ring to ultraviolet light.

The method may include lifting the edge support ring away from the semiconductor wafer.

The edge support ring may include a slope/slant.

The method may further include singulating the wafer into a plurality of die.

Implementations of methods of removing an edge support ring may include: providing a semiconductor wafer having a first side and a second side. The first side of the semiconductor wafer may include a backmetal. The semiconductor wafer may include an edge support ring around a perimeter of the semiconductor wafer. The method may include mounting a first side of the semiconductor wafer to a film frame and removing a portion of the backmetal around the edge support ring. The method may also include sawing at the removed portion of the backmetal to singulate the edge support ring from the semiconductor wafer along an inner portion of the edge support ring.

Implementations of methods of removing an edge support ring may include one, all, or any of the following:

The method may include further plasma etching two or more side walls between the edge support ring and the semiconductor wafer.

The semiconductor wafer may include a thickness less than 50 microns.

The method may further include exposing a tape coupled with the edge support ring to ultraviolet light.

The method may further include lifting the edge support ring away from the semiconductor wafer.

Removing a portion of the backmetal may include lasering, sawing, or wet etching.

The inner portion of the edge support ring may be one of sloped or non-sloped.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of semiconductor substrate having an edge support ring;

FIG. 2 is a cross sectional view of a portion of an implementation of a edge support ring on a substrate illustrating three potential locations for singulation;

FIG. 3 is a cross sectional view of the implementation of the edge support ring of FIG. 2 having the metal layer removed at the three potential locations for singulation;

FIG. 4 is a schematic of a cross sectional view of the implementation of the edge support ring of FIG. 3 on a substrate during plasma etching;

FIG. 5 is a cross sectional view of a portion of an implementation of a edge support ring on a substrate illustrating three potential locations for singulation;

FIG. 6 is a schematic of a cross sectional view of the implementation of the edge support ring of FIG. 6 on a substrate during plasma etching;

FIG. 7 is a cross sectional view of a portion of an implementation of an edge support ring on a substrate illustrating three locations for singulation through laser cutting; and

FIG. 8 is a cross sectional view of the implementation of the edge support ring of FIG. 7 having the metal layer removed at various locations for singulation.

### DESCRIPTION

This disclosure, its aspects and implementations, are not limited to the specific components, assembly procedures or method elements disclosed herein. Many additional components, assembly procedures and/or method elements known in the art consistent with the intended edge ring removal methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such edge ring removal methods, and implementing components and methods, consistent with the intended operation and methods.

Due to the miniaturization of packages, and the need for increased efficiencies in MOSFET devices, the typical die thickness for new devices is continually decreasing. New technologies are continually being developed for about 25-50 um thick dies to meet the industry requirements. A die singulation process which is optimal for about 10-100 um thick wafers may meet the requirements for the majority of new technologies.

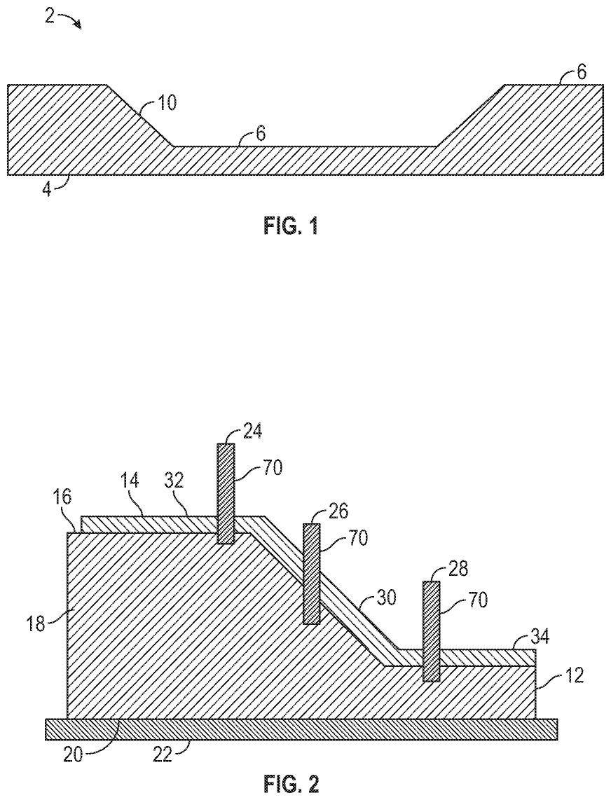

Referring to FIG. 1, a cross sectional side view of a substrate 2 having an edge ring is illustrated. The term “substrate” refers to a semiconductor substrate as a semiconductor substrate is a common type of substrate, however, “substrate” is not an exclusive term that is used to refer to all semiconductor substrate types. Similarly, the term “substrate,” may refer to a wafer as a wafer is a common type of substrate, however, “substrate” is not an exclusive term that is used to refer to all wafers. The various semiconductor substrate types disclosed in this document that may be utilized in various implementations may be, by non-limiting example, round, rounded, square, rectangular, or any other closed shape. In various implementations, the substrate 2 may include a substrate material such as, by non-limiting example, single crystal silicon, silicon dioxide, glass, gallium arsenide, sapphire, ruby, silicon on insulator, silicon carbide, polycrystalline or amorphous forms of any of the foregoing, and any other substrate material useful for constructing semiconductor devices. In particular implementations, the substrate may be a silicon-on-insulator substrate.

In various implementations disclosed in this document, the semiconductor substrate includes a plurality of semiconductor die that have been processed using a semiconductor fabrication process to form one or more semiconductor devices therein or thereon (not shown). The plurality of die have been processed on a first side 4 or active side of the semiconductor substrate. This may include forming a plurality of layers on a first side 4 the substrate. The plurality of layers may be patterned, and in various implementations, may be patterned (or otherwise removed) to not be over a die street/scribe line/die grid in the substrate. The plurality of layers may include, by non-limiting example, one or more metal layers, one or more passivation layers, any other layer, and any combination thereof. In various implementations, the plurality of die may include power semiconductor devices, such as, by non-limiting example, a MOSFET, an IGBT, or any other power semiconductor device. In other implementations, the plurality of die may include non-power semiconductor devices.

Following the completion of the fabrication process (or during some portion of it, in some implementations), the semiconductor substrate 2 is thinned on a side 6 of the semiconductor substrate that is opposite the side 4 on which the one or more semiconductor devices have been formed to a desired substrate thickness. In various implementations, the thinning process may create an edge ring 8 around the substrate (like that present in the backgrinding process marketed under the tradename TAIKO by Disco Hi-Tec America, Inc. of Santa Clara, Calif.). In various implementations, the edge ring 8 may be a sloped edge ring or include a slope 10 as illustrated. In other implementations, the edge ring may be non-sloped with an edge that is substantially perpendicular to the thinned surface of the substrate. The edge ring 8 acts to structurally support the substrate following thinning so that no carrier may need to be utilized during subsequent processing steps. In various implementations, the thinning process may be carried out after the semiconductor substrate has been mounted to a backgrinding tape whether an edge ring is formed during backgrinding or not. A wide variety of backgrinding tapes may be employed in various implementations, including those that are compatible with subsequent plasma etching operations. In other implementations, the semiconductor substrate may not be coupled to a backgrinding tape.

In various implementations, the substrate 2 may be thinned to an average thickness less than 50 microns (μm). As used herein, “average thickness” is a substrate average thickness across at least a majority of the largest planar surface of the substrate. In other implementations, the substrate may be thinned to an average thickness less than 30 μm. In still other implementations, the substrate may be thinned to an average thickness less than 100 μm, more than 100 μm, and in other various implementations, the substrate may not be thinned. In particular implementations, the substrate may be thinned to an average thickness of about 25 μm, and in other particular implementations, the substrate may be thinned to an average thickness of about 75 μm. The substrate may be thinned through backgrinding, etching, or any other thinning technique.

In various implementations, following the thinning process a metal layer is applied to a second side of the semiconductor substrate. In some implementations, the metal layer may be referred to as a backside metal layer or backmetal. In various implementations, the backmetal layer may be copper or a copper alloy. In some implementations, the metal may include tungsten, tin, gold, titanium, aluminum, silver, nickel, copper, chromium, alloys thereof, or any combination thereof. In other implementations, the backside metal layer may include any other type of metal, alloy thereof, or combination thereof. In various implementations, the backside metal layer may be about 10 μm thick. In other implementations, the backside metal layer may be more or less thick than 10 μm.

For semiconductor substrates that have an average thickness of less than 40 microns in thickness, particular processing challenges exist. Die handling, die strength, and performing processing operations with the die and substrates all present specific challenges, as die and substrate breakage can significantly reduce yield and/or affect device reliability. Die strength is negatively affected by traditional singulation options like sawing which induce die chipping and cracking along the die streets. These chips and cracks formed during the sawing process can eventually propagate during operation and reliability testing causing the die to fail. The method described herein may be used to remove edge support rings on ultrathin wafers and thicker wafers. It may be difficult to mount/hold/support the wafer onto a grinding wheel or other similar turntable structure for edge ring removal due to the thinness of the inner portion of the wafer. Plasma etching of the ring may also be difficult when a wafer includes a backmetal, including a seed metal or metal plate for solder attach.

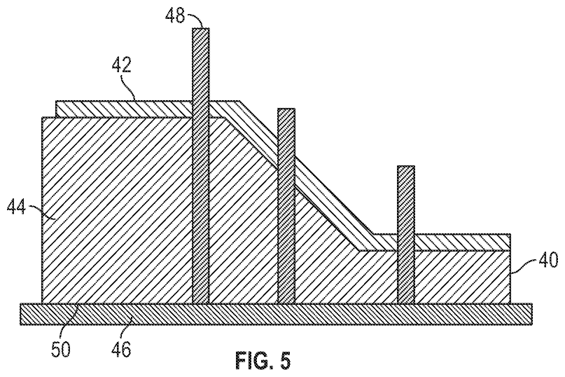

Various methods for removing an edge ring from a substrate may include providing a substrate having a first side and a second side. Referring to FIG. 2, a cross sectional view of a portion of an edge ring 18 is illustrated. The substrate includes a backmetal 14 on a second side 16 of the substrate 12. The backmetal 14 may include copper or any metals previously described herein. The method for removing the edge ring 18 may include mounting a first side 20 of the substrate to a tape 22 which may be supported by a film frame (not shown). In various implementations, the film frame may be made polyphenylene sulfide, styrene acrylonitrile, polyethylene terephthalate glycol (PETG), black conductive polystyrene, and other hard plastics. The tape may be a cutting tape, a picking tape, or a backgrinding tape in various implementations. As illustrated, the substrate may be positioned with the slope 30 of the edge ring 18 facing away from the film frame. A portion of the backmetal 14 is then removed around the edge support ring. In various implementations, the backmetal may be removed using a saw, laser, scribe, etch, any combination thereof, or other methods that are suitable for removing small portions of metal on a substrate. FIG. 2 illustrates three possible locations 24, 26, and 28 where the backmetal can be removed from the substrates, but these are non-limiting examples for the purposes of this disclosure, as other locations on the edge ring, off the edge ring, or along the sloped portion 30 could be selected. In the implementation illustrated in FIG. 2, a saw blade 70 is used to remove the portions of the backmetal 14. While FIG. 2 (and similarly, FIGS. 5 and 7) show three different locations where the backmetal is removed by a saw (or by a laser scribe tool, as illustrated by FIG. 7), it is understood that the various implementations disclosed herein only include removing the back metal at one of the three locations illustrated (or at another location different from the three locations illustrated). In various implementations, the edge ring 18 may include a slant/slope 30 as illustrated. In various implementations, optimal singulation of the wafer may be performed by making cuts along the slanted portion 30 of the edge support ring. In other implementations, the removal may occur along a flat surface 34 of the substrate or in the full thickness portion 32 of the edge ring 18. In still other variations, the face of the edge ring facing the thinned part of the substrate may be substantially perpendicular to the substrate and not include a slope.

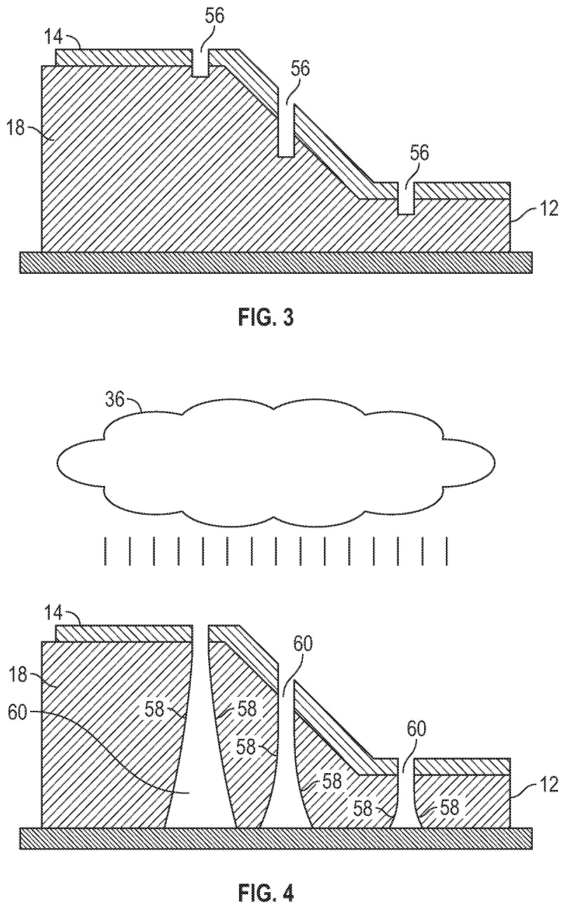

Referring to FIG. 3, a cross sectional view of the implementation of the edge ring of FIG. 2 having the backmetal removed at the three potential locations for singulation is illustrated. As illustrated, the backmetal 14 includes an opening 56 (or removed portion of the backmetal) that extends entirely through the backmetal. While FIG. 3 (and FIGS. 4, 6 and 8) illustrates three different openings, it is understood that these are potential locations of the openings and various implementations of the method disclosed herein include only forming one of the openings illustrated. In various implementations, the opening 56 may extend into substrate 12. In other implementations, the opening 56 does not extend into the substrate 12.

Referring to FIG. 4, an implementation of the edge ring 12 during plasma etching 36 is illustrated. The use of plasma etching is facilitated by the removal of the backmetal, which allows the plasma chemistry to contact the substrate material. As illustrated, the backmetal 14 works as a mask during the plasma etching process. In various implementations, the plasma etch may be carried out to ensure overetching of the substrate illustrated by the outward slopes to the sidewalls 58 of the etched regions 60. In other implementations, however, the plasma etching may be done to produce straight sidewalls or inwardly sloping sidewalls. In various implementations where the substrate is silicon, the etching may be carried out using the deep reactive ion plasma etching process marketed under the tradename BOSCH process by Robert Bosch Gmbh of Gerlingen, Germany. In other implementations, the edge support ring may be singulated through wet etching. Following the etching process, in some implementations, a tape coupled with the edge ring may be exposed to ultraviolet light to reduce the adhesive force between the tape and the material of the edge ring. In various implementations, the method may further include lifting the edge ring 18 away from the remainder of the substrate 12. The edge ring 18 may be removed using tweezers in various implementations. In other implementations, the edge ring 18 may be removed using a robotic arm or other automated tool.

After removal of the edge ring 18, further processing steps may be performed such as singulating the substrate into a plurality of die. In various implementations, the die may be singulated through plasma etching, sawing, wet etching, laser cutting, jet ablating, stealth dicing, and other methods for singulating die. In some implementations, singulation methods particular to ultrathin substrates may be used. The die may be singulated from a first side or from a second side of the substrate. In various implementations, the wafer may be singulated at the same time that the edge ring is singulated from the substrate.

Referring to FIG. 5, an implementation of a portion of a semiconductor wafer 40 having a backmetal 42 is illustrated. As illustrated, the edge ring 44 may be coupled to a tape 46 which may be supported by a film frame (not shown). The wafer may be positioned on the tape with the edge ring 44 facing up or away from the tape. In various implementations, the edge ring may be removed by sawing, using a saw 48, through the backmetal 42 of the wafer all the way to the first side 50 of the wafer 40. In some implementations, the edge ring 44 may be singulated using a laser scribe tool as illustrated in FIG. 7.

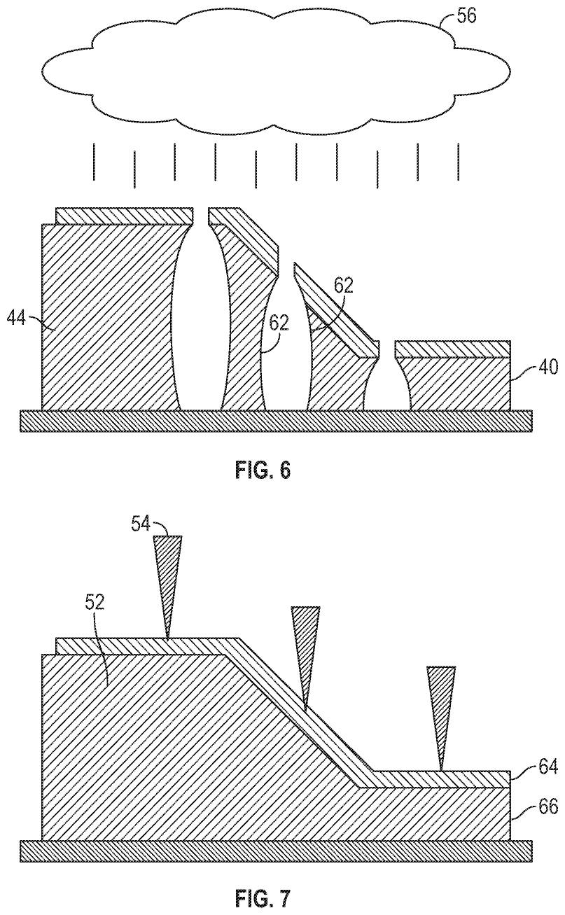

Referring to FIG. 6, an implementation of a wafer of FIG. 5 after sawing is illustrated. The method of singulating the edge ring 44 from the wafer may further include remote plasma healing through isotropic plasma etching 56 two or more side walls 62 between the edge support ring 44 and the semiconductor wafer 40 to remove side wall damage caused during the etching process. The wafer may be exposed to ultraviolet light after singulation so that the edge ring may be removed in some implementations. In various implementations, the method may further include lifting the edge support ring away from around the wafer. Further processing steps may be performed after removal of the edge support ring such as die singulation. In various implementations, die singulation may be performed simultaneously with edge support ring removal. In still other implementations, the edge support ring and die may be singulated through wet etching.

Referring to FIG. 7, a cross sectional view of a portion of an implementation of an edge ring on a substrate illustrating three locations for singulation through laser cutting is illustrated. Similar to the other implementations disclosed herein, particularly the implementation illustrated by FIG. 2, the method may include removing an edge ring 52 from a remainder of the substrate 66. In various implementations, a backmetal layer 64 may be coupled to substrate 66. The method of removing the edge ring 52 may include using a laser scribe tool 54 to remove the edge ring 52. While the laser scribe tool 54 may be used at any of the locations illustrated by FIG. 7, in other implementations the laser scribe tool may be used at other locations to remove the edge ring 52.

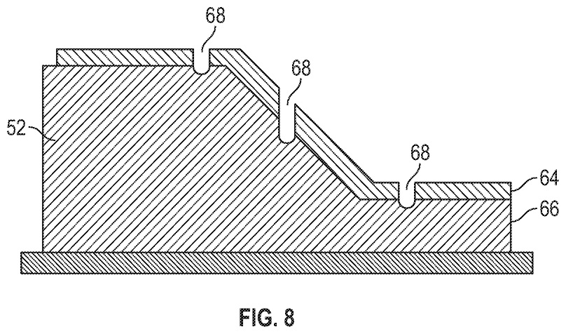

Referring to FIG. 8, a cross sectional view of the implementation of the edge support ring of FIG. 7 having the metal layer removed at various locations for singulation is illustrated. In various implementations, the method includes using the laser scribe tool 54 of FIG. 7 to form an opening 68 through the backmetal layer 64. As illustrated, in various implementations the opening 68 may extend partially into the substrate. In other implementations, the opening 68 may be formed just through the backmetal layer 64. Upon forming the opening through the backmetal layer, the edge ring 52 may be removed using any method disclosed herein, including the method of singulating the edge ring through an etch as illustrated by FIG. 4.

While the methods disclosed herein are focused on removing an edge ring from the substrate, it is understood that the substrate may include and/or be coupled to other elements not illustrated, such as a plurality of semiconductor devices formed therein or thereon the substrate. In such implementations, the plurality of semiconductor devices may include a power electronic semiconductor device or non-power electronic semiconductor device. In implementations where a plurality of power devices are coupled to the substrate, the power devices may include, by non-limiting example, a metal oxide field effect transistor (MOSFET), an insulated gate bipolar transistor (IGBT), a diode, a thyristor, a silicon controlled rectifier (SCR), or any other kind of power semiconductor device. Other devices such image sensors and other passive electronic components may be included in or on the material of the substrate.

In places where the description above refers to particular implementations of methods of removing edge support rings and implementing components, sub-components, methods and sub-methods, it should be readily apparent that a number of modifications may be made without departing from the spirit thereof and that these implementations, implementing components, sub-components, methods and sub-methods may be applied to other methods of removing edge support rings.

1. A method of removing an edge support ring, the method comprising:
providing a semiconductor wafer comprising a first side and a second side, the first side of the semiconductor wafer comprising a backmetal thereon, the semiconductor wafer comprising an edge ring around a perimeter of the semiconductor wafer;
mounting a first side of the semiconductor wafer to a film frame;
removing a portion of the backmetal around the edge support ring; and
singulating the edge support ring from the semiconductor wafer.

2. The method of claim 1, further comprising exposing the edge support ring to ultraviolet light.

3. The method of claim 1, further comprising lifting the edge support ring away from the semiconductor wafer.

4. The method of claim 1, wherein the edge support ring comprises a slope.

5. The method of claim 1, wherein the wafer has a thickness less than 50 microns.

6. The method of claim 1, further comprising singulating the wafer into a plurality of die.

7. The method of claim 1, wherein removing the portion of backmetal comprises sawing and laser.

8. The method of claim 1, wherein singulating the edge support ring from the semiconductor wafer comprises plasma etching and wet etching.

9. A method of removing an edge support ring, the method comprising:
providing a semiconductor wafer comprising a first side and a second side, the first side of the semiconductor wafer comprising a backmetal thereon, the semiconductor wafer comprising an edge ring around a perimeter of the semiconductor wafer;
mounting a first side of the semiconductor wafer to a film frame;
removing a portion of the backmetal around the edge support ring using sawing; and
plasma etching at the removed portion of the backmetal to singulate the edge support ring from the semiconductor wafer;
wherein the semiconductor wafer comprises a thickness less than 50 microns.

10. The method of claim 9, further comprising exposing a tape coupled with the edge support ring to ultraviolet light.

11. The method of claim 9, further comprising lifting the edge support ring away from the semiconductor wafer.

12. The method of claim 9, wherein the edge support ring comprises a slope.

13. The method of claim 9, further comprising singulating the wafer into a plurality of die.

14. A method of removing an edge support ring, the method comprising:
providing a semiconductor wafer comprising a first side and a second side, the first side of the semiconductor wafer comprising a backmetal thereon, the semiconductor wafer comprising an edge support ring around a perimeter of the semiconductor wafer;
mounting a first side of the semiconductor wafer to a film frame;
removing a portion of the backmetal around the edge support ring; and
sawing at the removed portion of the backmetal to singulate the edge support ring from the semiconductor wafer along an inner portion of the edge support ring.

15. The method of claim 14, further plasma etching two or more side walls between the edge support ring and the semiconductor wafer.

16. The method of claim 14, wherein the semiconductor wafer comprises a thickness less than 50 microns.

17. The method of claim 14, further comprising exposing a tape coupled with the edge support ring to ultraviolet light.

18. The method of claim 14, further comprising lifting the edge support ring away from the semiconductor wafer.

19. The method of claim 14, wherein removing a portion of the backmetal includes one of lasering, sawing, or wet etching.

20. The method of claim 14, wherein the inner portion of the edge support ring is one of sloped or non-sloped.
